(19) United States
(12) Patent Application Publication
(10) Pub. No.: US 2006/0128147 A1
(43) Pub. Date: Jun. 15, 2006

(54) Method of fabricating electrically conducting vias in a silicon wafer

(75) Inventor: Mohammed A. Fathimulla, Ellicott City, MD (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/008,436

(22) Filed: Dec. 9, 2004

(51) Int. Cl. H01L 21/44

(52) U.S. Cl. 438/660; 438/667; 438/799

(57) ABSTRACT

One or more electrically conducting vias are formed through a silicon substrate having a first surface, an opposite second surface, and a thickness between the first and second surfaces. A conductive metallic material is deposited on the first surface of the silicon substrate. For example, the metallic material may be deposited at one or more depressions in the first surface at one or more desired via locations. The conductive metallic material is migrated through the silicon substrate from the first surface to the second surface. For example, the conductive metallic material may be thermally migrated, and an oxide layer at the second surface may by used to terminate the migration.

### FIELD OF THE INVENTION

The invention is generally related to integrated circuit fabrication, and more particularly to the manufacture of electrically conducting through wafer vias holes in silicon semiconductor devices.

### BACKGROUND OF THE INVENTION

Silicon wafers having a front surface and a back surface are utilized to form integrated circuits. Additional layers of material are grown or otherwise deposited on the front surface of the silicon wafer, and these additional layers are processed to form various semiconductor device features of an integrated circuit. The back surface is typically a backplane for mounting the integrated circuit to a printed circuit board or other connector.

It is often desirable to provide conductive interconnects between the front or active surface of the silicon wafer and the back or backplane surface of the silicon wafer. In one example, an integrated circuit or chip can then be mounted to a printed circuit board with the back surface facing the board. The conductive interconnects couple circuit elements on the board to the circuits and devices of the integrated circuit.

In another example, a back metalized surface forms a ground plane for microstrip lines, and microwave and millimeter wave Integrated Circuits (MMICs). The conducting through wafer via connects the circuits on the front surface to the ground plane on the back surface. For such applications, low resistance, low inductance vias provide connectivity between front and back without the need for bond wires.

In still another example, a silicon wafer or substrate can be used to fabricate an integrated circuit used as a sensor. A sensor element is positioned on one surface (such as the back surface) of the substrate and various circuits and devices are formed in the multiple layers on the front surface. It is necessary to interconnect the sensor element with the circuitry for proper functioning of the device.

Electrically conducting vias extending between the front and back surfaces of the silicon substrate provide these connecting functions. Electrically conducting vias can also be utilized to create electrodes for the various circuits and devices of an integrated circuit chip.

One manner of fabricating conductive vias is to etch a hole through the silicon substrate so that the hole extends between the front and back surfaces of the wafer material. The surface of this hole is then plated or deposited or otherwise coated with a conductive material. For example, electrically conducting vias in silicon wafers are typically formed by first using a chemical wet etching process. The resulting hole is then electroplated or metallized in order to provide the conductive connection between the front and back surfaces. There are a number of problems with these known methods.

One problem is that the opening of the via hole at the surface of the substrate where the etch is started, typically the back surface, is relatively large. The etched via hole size limits the density or number of the electrically conducting vias that can be fabricated through a silicon substrate of a given surface area. This limited via hole density per unit surface area, therefore, determines the minimum substrate (and thickness) size that is permissible to manufacture a device requiring a known number of electrically conducting vias.

Also, the minimum diameter of an etched via hole is relatively large. Wet etching is a chemical reaction process that is performed from one surface of the substrate. The chemical reaction process cannot be so precisely controlled as to produce a hole diameter of any desired size. Therefore, the chemical reaction process has practical limits as to the minimum hole diameter. Moreover, the etch rate is limited (1-2 microns/minute) and therefore requires a long duration, typically 1-2 hours, to etch the via holes, which lowers the throughput. Further, the etch rate is diffusion or reaction limited, which slows down the etch rate.

As another result of the chemical reaction process, the etched hole has a larger diameter at the starting surface and a smaller diameter at the opposite surface. Thus, the via hole has tapered walls due to the isotropic nature of the chemical etch. Further, the chemical reaction cannot take place through significantly thick substrates without making the hole at the starting surface excessively large. Accordingly, there is a practical limit on the thickness of the silicon wafer as well.

A second approach for manufacturing through via holes is to use reactive ion etching or plasma etching. In addition, various sources such as high density plasma can be used with this approach. High density and anisotropic via holes can be fabricated with this technique. However, the technique requires toxic gases to achieve high etch rate. Further, the etch rate is size dependent, the etch rate is limited to 1-2 microns/min, and the loading effect is dominant.

Thermo-migration of aluminum through silicon has been recently developed for forming columns or pillars of aluminum on a silicon substrate for use as a neural interface in developing visual and other sensory restoration. The process includes providing a silicon substrate polished on one surface. An aluminum layer is deposited and then patterned to form metal squares on the substrate. The substrate is then subjected to a temperature gradient causing the aluminum to migrate through the substrate from the cooler surface to the opposite surface having the significantly elevated temperature. A selective chemical etch is then used to remove silicon material between the migrated aluminum to form very small, elongated pillars or columns extending from a silicon base.

The temperature gradient both across the surface area of the substrate and through the thickness of the substrate is preferably maintained so that the temperature gradient is uniform. Otherwise, the pillars are formed with different and/or non-uniform thicknesses and at angles that stray from the normal or perpendicular direction relative to the substrate surface.

Also, the aluminum during this thermo-migration process can migrate between pillars causing shorts between pillars in the finished product or causing breakage of pillars during the etching process. Irregularities in the crystalline structure of the silicon substrate can also cause variation in the aluminum thermo-migration results. Further, the square pads of aluminum when heated turn to droplets that can combine and migrate as one, thus forming a single pillar instead of two adjacent pillars. Avoiding some of these problems can be overcome by limiting the minimum spacing between the aluminum pads, and thus the pillars. However, limiting the spacing between pillars effectively limits the pillar density over the substrate surface area.

The present invention overcomes one or more of these or other problems of the prior art and also provides an innovative application of thermo-migration for the fabrication of through wafer via holes.

### SUMMARY OF THE INVENTION

In accordance with one aspect of the present invention, a method is provided to fabricate one or more electrically conducting vias through a silicon substrate having a first surface, an opposite second surface, and a thickness between the first and second surfaces. The method comprises the following: depositing a conductive metallic material on the first surface of the silicon substrate, the metallic material being positioned at one or more desired via locations; and, migrating the conductive metallic material through the silicon substrate from the first surface to the second surface until the conductive metallic material migrates from the first surface at the desired via locations to the second surface.

In accordance with another aspect of the present invention, a method is provided to fabricate at least one electrically conducting via through a semiconductor substrate having opposing first and second surfaces. The method comprises the following: removing a portion of the semiconductor substrate to create a via starting location; depositing a conductive material at the via starting location; and, creating a temperature gradient between the first surface and the second surface of the semiconductor substrate in order to migrate the conductive material so as to form the at least one electrically conducting via through the semiconductor substrate between the first and second surfaces.

In accordance with yet another aspect of the present invention, a method of fabricating an integrated circuit comprises the following: forming a depression in a first surface of a semiconductor substrate, wherein the semiconductor substrate has the first surface and a second surface, and wherein the first and second surfaces are opposing surfaces; depositing a conductive material at the depression; creating a temperature gradient between the first and second surfaces of the semiconductor substrate in order to migrate the conductive material so as to form an electrically conducting via through the semiconductor substrate between the first and second surfaces; and, forming a circuit element in additional layers so that the circuit element is coupled to the electrically conducting via, wherein one of the additional layers abuts one of the first and second surfaces.

### BRIEF DESCRIPTION OF THE DRAWINGS

Exemplary methods and electrically conducting vias in accordance with the teachings of the present invention are described and explained in greater detail below with the aid of the drawings in which:

FIG. 1 is a cross section of a silicon substrate semiconductor device fabricated utilizing a method according to the teachings of the present invention;

FIG. 2 is a cross section of a silicon substrate prior to beginning the method;

FIG. 3 illustrates the substrate shown in FIG. 2 after formation of a depression in the first surface and after formation of a pair of preliminary bores or holes through the substrate between the back and front surfaces;

FIG. 4 illustrates the substrate shown in FIG. 3 after depositing aluminum and an insulator or a sealing layer of polysilicon on the back surface of the substrate before the thermo-migration of the aluminum through the substrate;

FIG. 5 illustrates the substrate shown in FIG. 4 during thermo-migration of the aluminum through the substrate from the depression and through the preliminary bores;

FIG. 6 illustrates the substrate shown in FIG. 5 after thermo-migration of the aluminum to the front surface of the substrate is complete;

FIG. 7 illustrates the substrate shown in FIG. 6 after undergoing a planarization and wafer thinning process on the back surface;

FIG. 8 illustrates, as an alternative, the substrate shown in FIG. 4 and including a buried oxide layer of material added to the front surface prior to thermo-migration of the aluminum;

FIG. 9 illustrates the substrate shown in FIG. 8 after thermo-migration of the aluminum to the front surface is complete; and,

FIG. 10 illustrates the substrate shown in FIG. 7 and including a buried oxide layer of material on the front surface of the substrate.

### DETAILED DESCRIPTION

The detailed description below discloses examples of a method of fabricating an electrically conducting via through a semiconductor substrate such as a silicon wafer. The exemplary methods are described in conjunction with FIGS. 1-10. In general, the method utilizes a thermo-migration technique whereby a uniform temperature gradient through a thickness of a semiconductor substrate is created. A conductive material, such as aluminum, migrates from one surface of the substrate through its thickness to the opposite surface generally normal to a substrate surface at each location where the material is deposited on the substrate.

FIG. 1 shows a cross section of a simplified semiconductor device 20 that is fabricated utilizing methods according to the teachings of the present invention. As shown in FIG. 1, the semiconductor device 20 has a silicon substrate layer 22 with a semiconductor sealing layer 24 on a back surface of the silicon substrate layer 22. The sealing layer 24, for example, may be insulating or polysilicon material. A buried oxide layer 26 is carried on a front surface of the silicon substrate layer 22. An additional semiconductor layer 28 is carried on the buried oxide layer 26. A plurality of circuit devices and/or interconnects 32 are formed in various ones of the buried oxide 26 and the semiconductor layers 28 and 30. The circuit devices and/or interconnects 32 are formed using standard procedures and processes and are known to those having ordinary skill in the art. The circuit devices and/or interconnects 32 are passivated by a layer 30 using standard procedures and processes which are known to those having ordinary skill in the art. The semiconductor device 20 shown in FIG. 1 also includes a plurality of electrically conducting vias 40 formed between a back surface 42 and a front surface 44 of the silicon substrate layer 22. The electrically conducting vias 40 may be connected to circuits and devices.

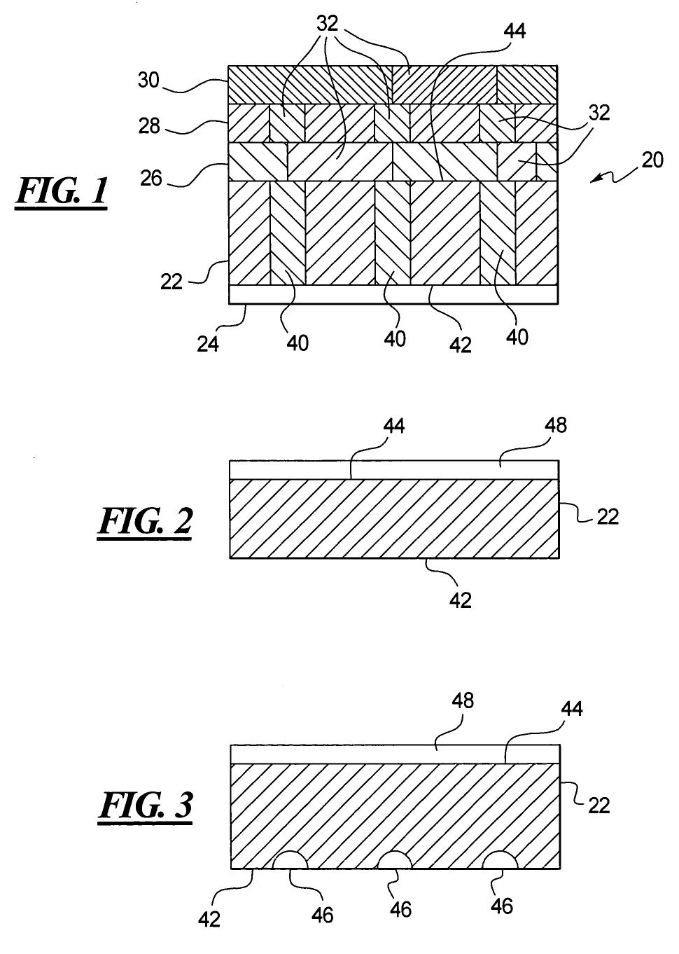

An exemplary method of fabricating the electrically conducting vias 40, applicable for example to bulk silicon and n accordance with the teachings of the present invention is described with reference to FIGS. 2-7. FIG. 2 illustrates the silicon substrate layer 22 having the back surface 42, the front surface 44, and a thickness between the back and front surfaces 42 and 44. The front surface 44 may have an oxide layer 48 where the thermal migration terminates. The oxide layer 48 is grown or deposited during the CMOS process. This layer can be buried oxide (layer 26) in the case of Silicon on Insulator as the starting substrate. One or more depression 46 are formed in the back surface 42 of the silicon substrate layer 22.

A dollop of high conductivity, relatively low melting point conductive material 50, such as aluminum or an aluminum based metallic composition, is deposited over each of the one or more depressions 46 on the back surface 42 of the silicon substrate layer 22. Thus, as shown in FIG. 4, the conductive material 50 is deposited locally at each of the depressions 46. The sealing layer 24, such as insulating layer or a polysilicon layer, is deposited on the back surface 42. The sealing layer 24 helps prevent out-diffusion of aluminum from the back plane surface, and also helps to prevent contamination of the processing equipment. Also, as shown in FIG. 4, a substantially uniform temperature gradient AT is created by heating the front surface 44 of the silicon substrate layer 22 to a higher temperature than the back surface 42. The temperature gradient AT is preferably on the order of less than 1,000° C., with the temperature increasing from the back surface 42 to the front surface 44. To avoid any additional thermal budget, this temperature processing step can be combined with the standard processing of the silicon-CMOS process.

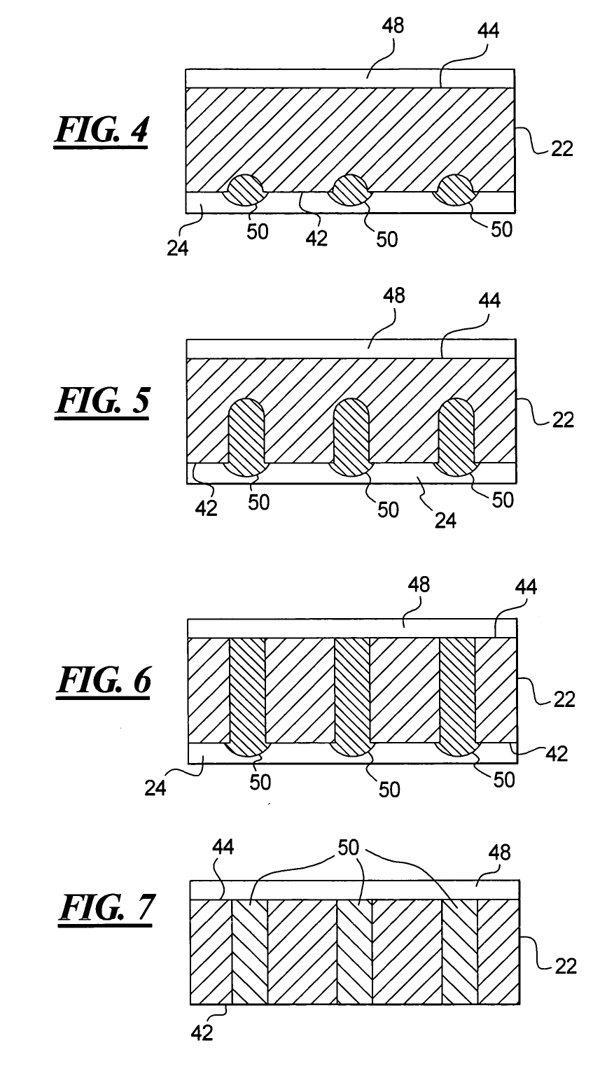

The temperature gradient with the higher temperature toward the front surface 44 of the silicon substrate layer 22 causes the melted conductive material 50 to migrate through the silicon substrate layer 22 from the back surface 42 to the front surface 44. FIG. 5 illustrates the silicon substrate layer 22 as the conductive material 50 is migrating toward the front surface 44. FIG. 6 illustrates completed aluminum migration to the front surface 44 of the silicon substrate layer 22. The aluminum migration terminates at the oxide layer 48.

In the exemplary embodiment of the invention described above, the back surface 42 requires additional finishing, such as a chemical etch and/or a mechanical polish, to remove the sealing layer 24 and excess aluminum material. FIG. 7 illustrates the back surface 42 after undergoing a chemical etch and/or a mechanical polish process that creates a smooth planar surface for the back surface 42 and thins the silicon substrate layer 22.

An aluminum migrated layer may be formed as a result of the above processing. This aluminum migrated layer is highly doped silicide and forms a contact between the top and back surfaces of the silicon wafer. However, it provides higher resistance. Therefore, a wet chemical etch can be is used to remove this layer to form the via-holes in substrate layer 22 and metal can be deposited to form low resistance contacts.

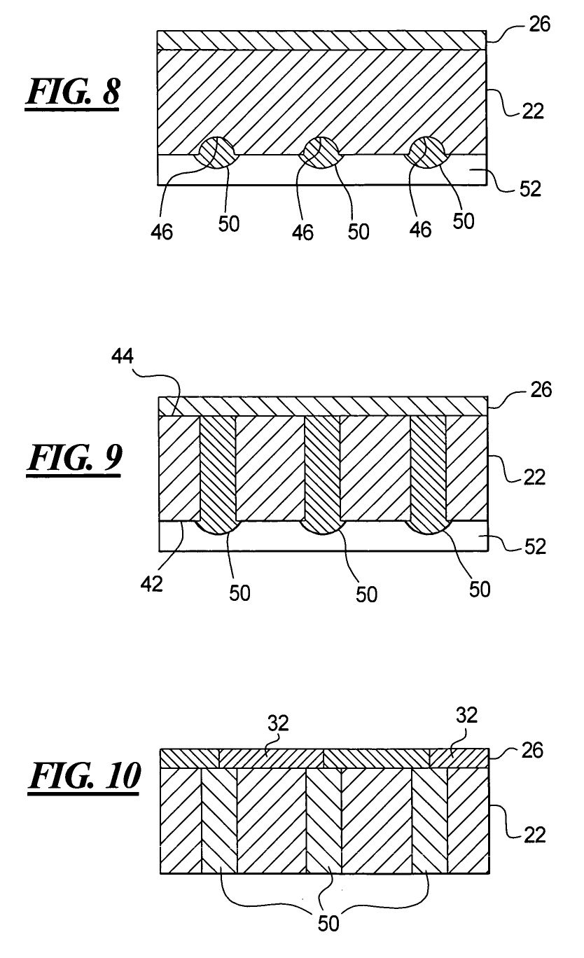

The process can also be applied to Silicon on Insulator based devices and circuits. In an SOI substrate, the layer 26 is buried oxide, the layer 28 (not shown in FIGS. 8 and 9) is a silicon film, and the layer 22 is a silicon substrate. FIGS. 8 and 9 illustrate steps prior to migrating the conductive material 50 from the back surface 42 to the front surface 44 of the SOI substrate.

An additional sealing layer 52 of insulating or polysilicon material can then be added to the back surface 42 as shown in FIG. 8. As shown in FIG. 9, the conductive material 50 is then thermally migrated as before. The buried oxide layer 26 in this example automatically terminates the migration of the conductive material 50 at the buried oxide layer 26. Thus, as shown in FIG. 9, the conductive material 50 migrates to the front surface 44 of the silicon substrate layer 22, but further migration is blocked by the buried oxide layer 26. The silicon substrate layer 22 as shown in FIG. 10 can then be further processed on the back surface 42 to etch the sealing layer, eliminate the excess aluminum, and thin the silicon layer 22 as described previously with regard to FIG. 7.

The aluminum migrated layer is highly doped silicide and therefore gives higher resistance contact between top and back surface of the silicon wafer. Therefore, a wet chemical etched to remove this layer to form via-hole in substrate layer 22 and deposited metal is used to lower the contact resistance.

Later fabrication steps, as exemplified in FIG. 1, are performed to form various circuit components, devices, paths, and/or interconnect as desired.

As shown in FIG. 1, the buried oxide layer 26 can be further processed by chemical etching and metalization procedures and by other known processes to form the circuit devices and/or interconnects 32 of a desired integrated circuit device, such as the semiconductor device 20 shown in FIG. 1. Thus, as illustrated in FIG. 1 for example, the semiconductor layers 28 and 30, as well as other layers, can be added to the buried oxide layer 26. The circuit devices and/or interconnects 32 can be fabricated in each additional layer.

The disclosed process in accordance with the teachings of the present invention utilizes the migration of aluminum or other metal in order to form the plurality of closely spaced electrically conducting vias 40 extending between the back surface 42 and the front surface 44 of the silicon substrate layer 22. The process can provide a high density per unit area of electrically conducting vias in silicon. The electrically conducting vias can also be precisely placed as desired by simply forming the depressions 46. This process is also not limited by the particular thickness between the back surface 42 and front surface 44 of the silicon substrate layer 22 as in prior known interconnect forming processes. Moreover, the depressions 46 need not be provided. However, the depressions 46 facilitate the electrically conducting vias 40 having substantially uniform thicknesses, angles that are normal or perpendicular relative to the back and front surfaces 42 and 44, and/or substantially no shorts therebetween.

A thick metal can be deposited on the back surface 42 to connect the front surface 44 to the back surface 44 with the thick metal on the back surface 44 acting as a ground plane. Alternately, a seed layer can be deposited on the back surface 42 and the thick metal, such as gold, can be electroplated.

Although certain methods and vias have been disclosed and described herein in accordance with the teachings of the present invention, the scope of coverage of this patent is not limited thereto. On the contrary, this patent covers all embodiments of the teachings of the invention fairly falling within the scope of the appended claims, either literally or under the doctrine of equivalents.

What is claimed is:

1. A method of fabricating one or more electrically conducting vias through a silicon substrate having a first surface, an opposite second surface, and a thickness between the first and second surfaces, the method comprising:
depositing a conductive metallic material on the first surface of the silicon substrate, the metallic material being positioned at one or more desired via locations; and,
migrating the conductive metallic material through the silicon substrate from the first surface to the second surface until the conductive metallic material migrates from the first surface at the desired via locations to the second surface.

2. The method of claim 1 wherein the migrating of the conductive metallic material comprises maintaining a temperature gradient between the first and second surfaces of the substrate so as to cause migration of the conductive metallic material from the first surface to the second surface.

3. The method according to claim 1 wherein the depositing of a conductive metallic material on the first surface of the silicon substrate comprises:
forming a depression in the first surface of the silicon substrate at each of the one or more desired via locations; and,
depositing the conductive metallic material at the depression formed at each of the one or more desired via locations.

4. The method according to claim 1 further comprising polishing the first surface of the silicon substrate.

5. The method according to claim 1 further comprising adding a layer of polysilicon to the first surface of the substrate subsequent to the migration of the conductive metallic material.

6. The method according to claim 1 wherein an oxide layer abuts the second surface, and wherein the method further comprises forming integrated circuit elements coupled to the one or more electrically conducting vias through the oxide layer.

7. The method according to claim 6 wherein the oxide layer results from CMOS processing of the silicon substrate.

8. The method according to claim 6 wherein the oxide layer is a buried oxide layer of an SOI structure.

9. The method according to claim 1 further comprising forming integrated circuit elements coupled to the one or more electrically conducting vias.

10. The method of claims 1 wherein an oxide layer abuts the second surface of the silicon substrate, and wherein the migration of the conductive metallic material through the silicon substrate terminates at the oxide layer.

11. The method according to claim 10 wherein the oxide layer results from CMOS processing of the silicon substrate.

12. The method according to claim 10 wherein the oxide layer is a buried oxide layer of an SOI structure.

13. A method of fabricating at least one electrically conducting via through a semiconductor substrate having opposing first and second surfaces, the method comprising:
removing a portion of the semiconductor substrate to create a via starting location;
depositing a conductive material at the via starting location; and,
creating a temperature gradient between the first surface and the second surface of the semiconductor substrate in order to migrate the conductive material so as to form the at least one electrically conducting via through the semiconductor substrate between the first and second surfaces.

14. The method according to claim 13 wherein the removing of a portion of the semiconductor substrate to create the via starting location comprises forming a depression in the first surface of the semiconductor substrate.

15. The method according to claim 13 wherein the semiconductor substrate comprises a silicon substrate.

16. The method according to claim 13 wherein the conductive material comprises aluminum.

17. The method according to claim 13 further comprising performing a planarization process on the first surface.

18. The method according to claim 13 further comprising adding a layer of polysilicon to the first surface of the semiconductor substrate subsequent to the migration of the conductive material.

19. The method according to claim 13 wherein an oxide layer abuts the semiconductor substrate, and wherein the method further comprises forming integrated circuit elements coupled to the at least one electrically conducting via through the buried oxide layer.

20. The method according to claim 13 further comprising forming integrated circuit elements coupled to the at least one electrically conducting via.

21. The method of claims 13 wherein an oxide layer abuts the second surface of the semiconductor substrate, wherein the removing of a portion of the semiconductor substrate to create a via starting location comprises forming a depression in the first surface of the semiconductor substrate, wherein the depositing of a conductive material at the via starting location comprises depositing the conductive material in the depression, and wherein the oxide layer terminates the migration of the conductive metallic material through the semiconductor substrate.

22. The method according to claim 21 wherein the oxide layer results from CMOS processing of the semiconductor substrate.

23. The method according to claim 21 wherein the oxide layer is a buried oxide layer of an SOI structure.

24. A method of fabricating an integrated circuit comprising:
forming a depression in a first surface of a semiconductor substrate, wherein the semiconductor substrate has the first surface and a second surface, and wherein the first and second surfaces are opposing surfaces;
depositing a conductive material at the depression;
creating a temperature gradient between the first and second surfaces of the semiconductor substrate in order to migrate the conductive material so as to form an electrically conducting via through the semiconductor substrate between the first and second surfaces; and,
forming a circuit element in additional layers so that the circuit element is coupled to the electrically conducting via, wherein one of the additional layers abuts one of the first and second surfaces.

25. The method according to claim 24 wherein one of the additional layers comprises a buried oxide layer.

26. The method according to claim 25 wherein the buried oxide layer terminates migration of the conductive material at the second surface.

27. The method according to claim 24 wherein one of the additional layers results from CMOS processing of the semiconductor substrate.

28. The method according to claim 27 wherein the oxide layer terminates migration of the conductive material at the second surface.
